(19) United States
(12) Patent Application Publication
(10) Pub. No.: US 2023/0204659 A1
(43) Pub. Date: Jun. 29, 2023

(54) MICRO DEVICE UNDER TEST CARRIER

(71) Applicant: CHROMA ATE INC., TAOYUAN CITY (TW)

(72) Inventors: Chun-Lin WU, TAOYUAN CITY (TW); Kuo Wei HUANG, TAOYUAN CITY (TW)

(21) Appl. No.: 17/981,167

(22) Filed: Nov. 4, 2022

(30) Foreign Application Priority Data
Dec. 29, 2021 (TW) 110149382

(51) Int. Cl. G01R 31/28

(52) U.S. Cl. CPC G01R 31/2889

(57) ABSTRACT

A micro device under test (DUT) carrier includes a carrier main body, a pusher and a spring. The carrier main body includes a plurality of bearing stages. Each bearing stage is utilized to bear a micro DUT. The pusher, operated to move from a locking position to an opening position, includes a pusher main body and a plurality of locking elements. Each locking element corresponds to each bearing stage, and is located next to each bearing stage. The spring is utilized to send the pusher back to the locking position, so that each locking element restricts movement of each micro DUT.

### CROSS REFERENCE TO RELATED APPLICATION

This application claims the benefits of Taiwan application Serial No. 110149382, filed Dec. 29, 2021, the disclosures of which are incorporated by references herein in its entirety.

### BACKGROUND OF THE INVENTION

### (1) Field of the Invention

The invention relates to a carrier, and more particularly to a micro DUT (device under test) carrier.

### (2) Description of the Prior Art

While in manufacturing a micro element such as an edge-emitting laser diode, a testing is usually performed thereupon under different surroundings including, for example, a high-temperature environment and a low-temperature environment. The testing may involve plural micro elements, and may include an electricity test, an energy test, an optical test and so on.

Referring to FIG. 1, a schematic perspective view of a conventional micro DUT carrier is shown. This micro DUT carrier PA1 is furnished with a plurality of bearing cavities PAT1 individually for carrying thereon a plurality of micro DUTs U1, U2, and allows these micro DUTs U1, U2 to electrically connect respective probes so as to generate corresponding laser beams Each of the micro DUTs U1, U2 can be an edge-emitting laser (EEL) diode. Thus, the probes can touch onto the corresponding micro DUTs U1, U2 so as to have laser beams emitted laterally outward from both sides of the micro DUTs U1, U2, referred to FIG. 9.

Nevertheless, the conventional micro DUT carrier PA1 is provided with a vacuum hole PAH1 for vacuuming thereon the micro DUTs U1, U2. While the probes retrieve from the corresponding micro DUTs U1, U2, the micro DUTs U1, U2 would be lifted and dropped therewith. Possibly, due that the retrieving probes would temporarily drag the micro DUTs U1, U2 therealong, the dragged micro DUTs U1, U2 might be pulled off the micro DUT carrier PAL In addition, since sizes of the micro DUTs U1, U2 are too small to be accurately positioned, thus a need for improving the aforesaid carrier structure is always there.

### SUMMARY OF THE INVENTION

In view that the retrieving of the probes may dislocate the micro DUTs in the art, and from which various shortcomings such as dropping off and ill positions may be inevitable, accordingly it is an object of the present invention to provide a micro DUT carrier for resolving at least one of those shortcomings in the art.

In this invention, a micro DUT carrier is applied for bearing a plurality of micro DUTs and allowing the plurality of micro DUTs to be energized individually by a plurality of probes so as to generate a plurality of light beams. The micro DUT carrier includes a carrier main body, a pusher and a spring. The carrier main body includes a plurality of bearing stages separated to each other and arranged in an extension direction. Each of the plurality of bearing stages is configured for bearing one of the plurality of micro DUTs. The pusher, disposed at the carrier main body and controlled to move in the extension direction from a locking position to an opening position, includes a pusher main body and a plurality of locking elements. The pusher main body is extended in the extension direction. Each of the plurality of locking elements is extended from the pusher main body in a restraint direction substantially perpendicular to the extension direction, and is disposed in a gap between adjacent two of the plurality of bearing stages. Also, each of the plurality of locking elements has a protrusive portion extending backward with respect to the extension direction. While in the locking position, each of the plurality of micro DUTs is restrained correspondingly at each of the plurality of bearing stages. The spring is disposed between the carrier main body and the pusher. After the pusher is controlled to be pushed to the opening position for disposing the plurality of micro DUTs, the spring provides elastic resilience to send the pusher back to the locking position so as to have the plurality of locking elements to restrain correspondingly the plurality of micro DUTs.

In one embodiment of the present invention, each of the plurality of bearing stages further includes a bearing portion and a restraint portion. The bearing portion has a bearing plane for bearing one of the plurality of micro DUTs. The restraint portion is connected with the bearing portion to form a restraint plane for contacting against each of the plurality of micro DUTs.

In one embodiment of the present invention, each of the plurality of bearing stages further includes a positioning portion disposed on the bearing plane of the bearing portion, separated from the restraint portion, and configured to auxiliarily limit each of the plurality of micro DUTs.

In one embodiment of the present invention, each of the plurality of bearing stages further includes a positioning portion disposed on the bearing plane of the bearing portion, connected with the restraint plane of the restraint portion, and configured to auxiliarily limit each of the plurality of micro DUTs.

In one embodiment of the present invention, each of the plurality of locking elements further includes an extension portion extended in the restraint direction from the pusher main body and connected with the protrusive portion.

In one embodiment of the present invention, the protrusive portion is furnished with a top cutout configured for allowing one of the plurality of probes to enter and then touch electrically corresponding one of the plurality of micro DUTs.

In one embodiment of the present invention, the protrusive portion is furnished with a lateral cutout configured to pass therethrough the plurality of light beams upon when the corresponding one of the plurality of micro DUTs is energized by the one of the plurality of probes.

In one embodiment of the present invention, the extension portion has an extended positioning wall for contacting against the corresponding one of the plurality of micro DUTs upon when the pusher is moved back to the locking position.

In one embodiment of the present invention, the protrusive portion has an overhead restraint protrusion for contacting against the corresponding one of the plurality of micro DUTs upon when the pusher is moved back to the locking position.

In one embodiment of the present invention, each of the plurality of bearing stages is furnished with a vacuum hole for auxiliarily sucking one of the plurality of micro DUTs.

As stated above, the present invention utilizes the carrier main body, the pusher and the spring to bear a plurality of micro DUTs, and allows the micro DUTs to be individually energized by a plurality of probes so as to generate a plurality of laser or light beams. In comparison to the prior art, the present invention utilizes the pusher to be controllably moved between the locking position and the opening position. While in the opening position, the carrier main body can be ready to bear the micro DUTs. The elastic resilience of the spring is utilized to send the pusher back to the locking position. Upon such an arrangement, the locking elements can be applied to restrain the micro DUTs on the corresponding bearing stages, and thus the conventional shortcomings in dropping the micro DUTs while the probes are retrieved can be resolved. In addition, in the present invention, the restraint plane of the restraint portion provides a further moving limitation to the micro DUTs in another direction. Further, the present invention further provides the positioning portion to contribute one more moving limitation to the micro DUTs in a further direction. Thus, beside the aforesaid directional moving limitations provided by the present invention, the positioning accuracy of the micro DUTs can be substantially enhanced. Furthermore, the conventional vacuum holes are also provided in the present invention for vacuuming the corresponding micro DUTs auxiliarily in both positioning and moving limitations.

All these objects are achieved by the micro DUT carrier described below.

### BRIEF DESCRIPTION OF THE DRAWINGS

The present invention will now be specified with reference to its preferred embodiment illustrated in the drawings, in which:

FIG. 1 is a schematic perspective view of a conventional micro DUT carrier;

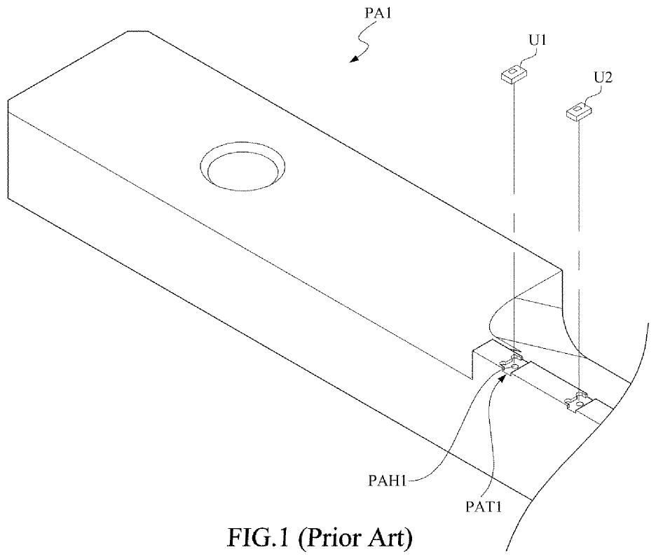

FIG. 2 is a schematic perspective view of a first embodiment of the micro DUT carrier in accordance with the present invention;

FIG. 3 is a schematic cross-sectional view of FIG. 2 along line A-A;

FIG. 4 demonstrates schematically a process of loading the micro DUT into the micro DUT carrier of FIG. 2;

FIG. 5 demonstrates schematically a state of the micro DUT loaded in the micro DUT carrier of FIG. 2;

FIG. 6 demonstrates schematically the positioning of the micro DUT loaded in the micro DUT carrier of FIG. 2;

FIG. 7 is a schematic cross-sectional view of FIG. 6 along line B-B;

FIG. 8 is a schematic side view of FIG. 6;

FIG. 9 demonstrates schematically generation of laser beams after the probe contacts electrically the micro DUT loaded at the micro DUT carrier of FIG. 2;

FIG. 10 demonstrates schematically a process of loading the micro DUT into a second embodiment of the micro DUT carrier in accordance with the present invention;

FIG. 11 demonstrates schematically the positioning of the micro DUT loaded in the micro DUT carrier of FIG. 10; and

FIG. 12 is a schematic side view of FIG. 11.

### DESCRIPTION OF THE PREFERRED EMBODIMENT

The invention disclosed herein is directed to a micro DUT carrier. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

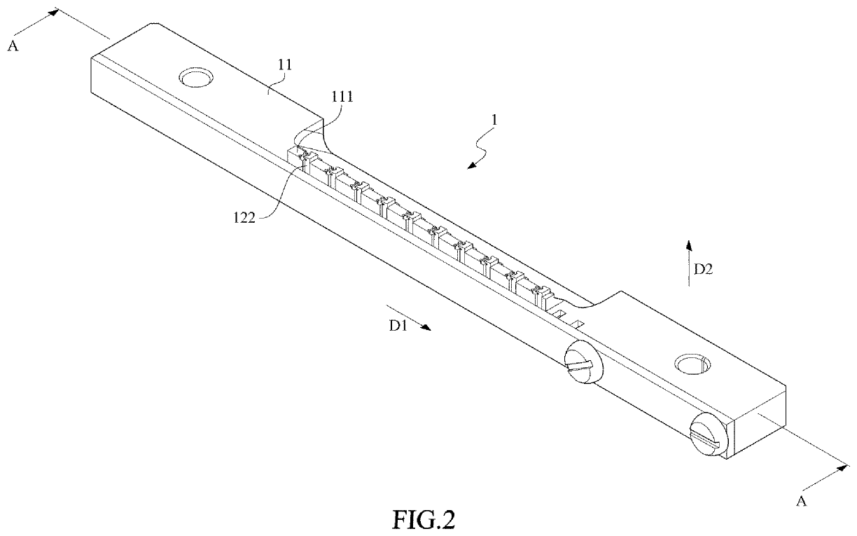

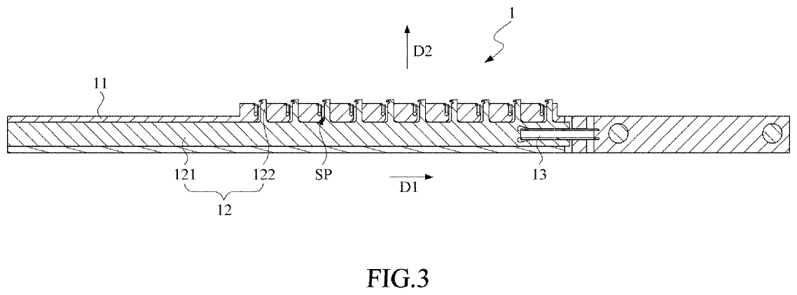

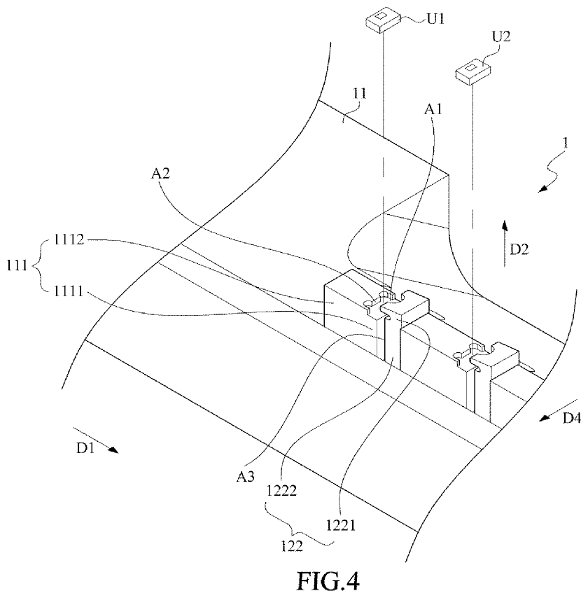

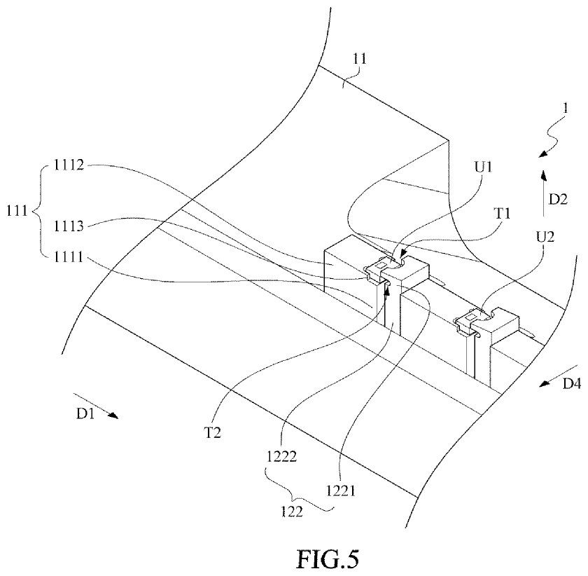

Refer to FIG. 2 through FIG. 5; where FIG. 2 is a schematic perspective view of a first embodiment of the micro DUT carrier in accordance with the present invention, FIG. 3 is a schematic cross-sectional view of FIG. 2 along line A-A, FIG. 4 demonstrates schematically a process of loading the micro DUT into the micro DUT carrier of FIG. 2, and FIG. 5 demonstrates schematically a state of the micro DUT loaded in the micro DUT carrier of FIG. 2. As shown, the micro DUT carrier 1, configured for bearing a plurality of micro DUTs U1, U2 (two shown in the figure), includes a carrier main body 11, a pusher 12 and a spring 13. In the following description, the micro DUT U1 would be particularly picked as an example for the micro DUTs in the embodiment including the micro DUT U2. Generally speaking, the term “micro” is directed to an element having a dimension less than 3 mm. Practically, the micro DUT U1 of this embodiment has a length close to 0.05 mm.

As shown in FIG. 2, the carrier main body 11 includes a plurality of bearing stages 111 (one labeled in the figure) separated to each other and extending in an extension direction D1. Each of the bearing stages 111 is configured for bearing one of the aforesaid micro DUTs U1. As shown in FIG. 4, in this embodiment, the bearing stage 111 includes a bearing portion 1111, a restraint portion 1112 and a positioning portion 1113. The bearing portion 1111 has a bearing plane A1 for bearing the corresponding micro DUT U1. The restraint portion 1112 is connected with the bearing portion 1111 to form a restraint plane A2. A show in the figures, since the restraint portion 1112 is higher than the bearing portion 1111, thus a vertical restraint plane A2 would be formed at a portion of the restraint portion 1112 above the bearing portion 1111. The restraint plane A2 is applied for contacting against the respective micro DUT U1. The positioning portion 1113, disposed on the bearing plane A1, is connected with the restraint plane A2.

As shown in FIG. 3 and FIG. 4, the pusher 12, disposed at the carrier main body 11, includes a pusher main body 121 and a plurality of locking elements 122. When a user (not shown in the figure) pushes the pusher 12 in the extension direction D1 so as to move the pusher 12 from a locking position to an opening position, such that the micro DUT U1 can be placed onto the corresponding bearing stage 111.

The pusher main body 121, extending in the extension direction D1, can undergo relative displacements with respect to the carrier main body 11. Each of the locking elements 122 is protruded from the pusher main body 121 in a restraint direction D2. Preferably, the restraint direction D2 is substantially perpendicular to the extension direction D1. As shown in FIG. 3 and FIG. 4, each of the locking elements 122 is corresponding to a bearing stage 111, and disposed in a gap SP formed between the two adjacent bearing stages 111. The locking element 122 includes a protrusive portion 1221 and an extension portion 1222. The extension portion 1222 is protruded from the pusher main body 121 and extended in the restraint direction D2. In this embodiment, the extension portion 1222 has an extended positioning wall A3. The protrusive portion 1221, protruding further from the extension portion 1222 in a direction opposing the extension direction D1, is structured to have a top cutout T1 and a lateral cutout T2. As shown from FIG. 3 to FIG. 5, while the pusher 12 is at an opening position, each of the locking elements 122 would be separated from the corresponding bearing stage 111, such that enough rooms would be formed for the micro DUT U1 to be positioned on the corresponding bearing stage 111.

After the micro DUT U1 is rested on the corresponding bearing stage 111, the positioning portion 1113 would limit the micro DUT U1 at one direction. As shown in the figure, the positioning portion 1113 would limit the movement of the micro DUT U1 at a first direction D4. Substantially, the first direction D4 is perpendicular to both the extension direction D1 and the restraint direction D2.

The spring 13, disposed between the carrier main body 11 and the pusher 12, provides elastic resilience to push the pusher 12. Practically, while the pusher 12 is pushed to move in the extension direction D1, the spring 13 would be depressed in the extension direction D1 by the pusher 12.

The carrier main body 11 can be a unique part or a multi-piece part. In this embodiment, the carrier main body 11 is shown to be a multi-piece (two-piece) part to mount the pusher 12 and the spring 13 individually.

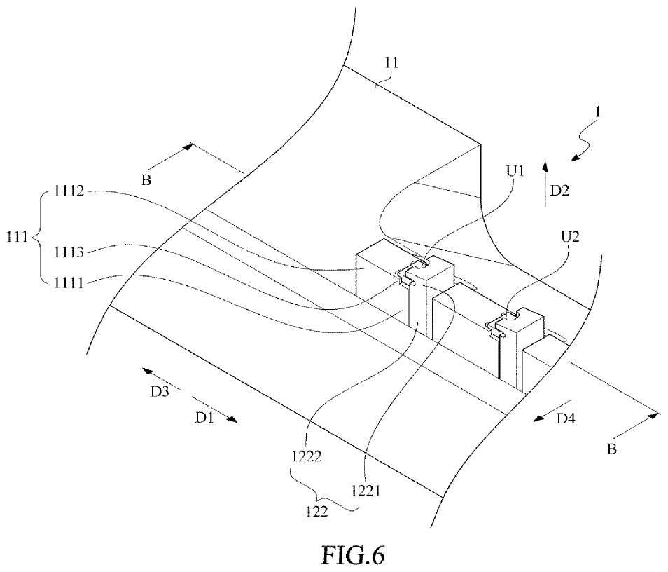

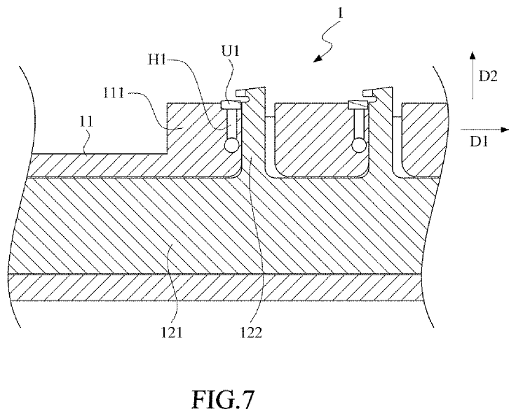

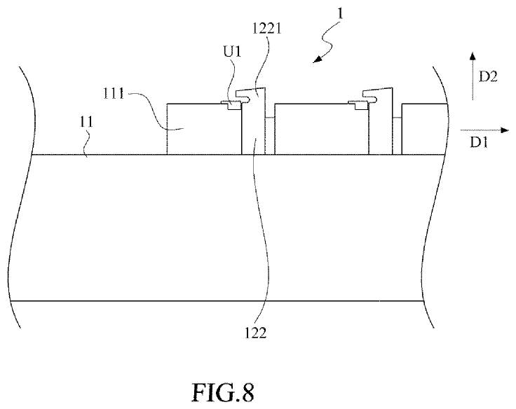

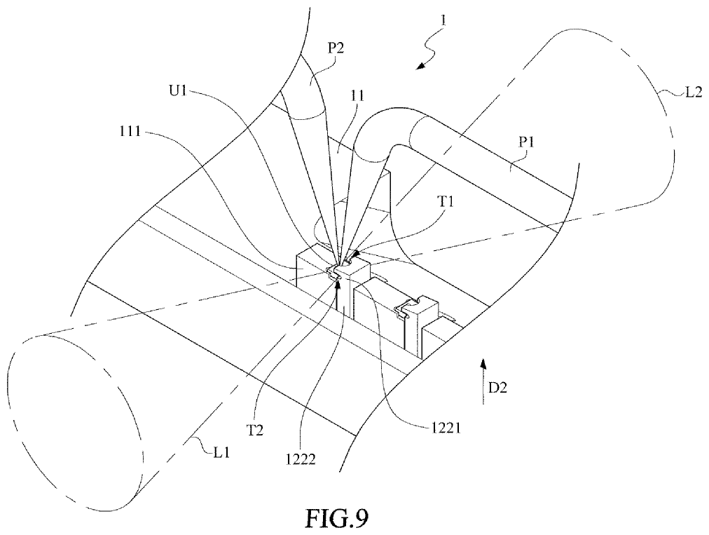

Then, refer to FIG. 3 through FIG. 9 together; where FIG. 6 demonstrates schematically the positioning of the micro DUT loaded in the micro DUT carrier of FIG. 2, FIG. 7 is a schematic cross-sectional view of FIG. 6 along line B-B, FIG. 8 is a schematic side view of FIG. 6, and FIG. 9 demonstrates schematically generation of laser beams after the probe contacts electrically the micro DUT loaded at the micro DUT carrier of FIG. 2. As shown in FIG. 5 and FIG. 6, when the bearing stage 111 is loaded thereon with the micro DUT U1, and the action forcing upon the pusher 12 is removed, the spring 13 would relieve the elastic resilience to push the pusher 12 to move in a reset direction D3 so as to push the pusher 12 back to the locking position.

At this time, each of the locking elements 122, disposed by closing to the corresponding bearing stage 111, is configured for locating the micro DUT U1 onto the corresponding bearing stage 111.

As shown in FIG. 4 and FIG. 5, the locking element 122 and the restraint plane A2 of the corresponding restraint portion 1112 are integrated to limit the movement of the micro DUT U1 in the extension direction D1. Further, as shown in FIG. 4 and FIG. 7, the restraint plane A2 of the restraint portion 1112 and the extended positioning wall A3 of the extension portion 1222 would contact individually against two opposite sides of the micro DUT U1, such that the movement of the micro DUT U1 in the extension direction D1 can be limited. As shown in FIG. 8, the protrusive portion 1221 of the locking element 122 would be located above the micro DUT U1, such that the movement of the micro DUT U1 in the restraint direction D2 can be limited.

As shown in FIG. 9, then, a plurality of probes can be applied. Practically, two probes P1, P2 can be introduced downward to electrically touch and energize the micro DUT U1, and then the energized micro DUT U1 would generate a plurality of laser beams L1, L2. In this embodiment, the micro DUT U1 is an edge-emitting laser (EEL) diode, and thus the laser beams L1, L2 would be emitted from edges of the micro DUT U1. Since these two probes P1, P2 are introduced downward to contact electrically the micro DUT U1, and the protrusive portion 1221 is there to limit the upward movement of the micro DUT U1, thus the protrusive portion 1221 is furnished with a top cutout T1 to avoid any structural interference with any of the two probes P1, P2 (the probe P1 in the figure). Namely, the protrusive portion 1221 can allow the probe P1 to enter, and can also limit the movement of the micro DUT U1 in the restraint direction D2 (upward). In addition, the protrusive portion 1221 is furnished with lateral cutouts T2 to pass the laser beams L1, L2 generated by the micro DUT U1. Thereupon, following tests related to the laser beams L1, L2 can be performed.

Practically, the probes P1, P2 are to contact a pad on the micro DUT U1, and thus any of the two probes P1, P2 shall be harder than the pad. As long as the testing is over, the two probes P1, P2 would be retrieved upward in the restraint direction D2 to leave the micro DUT U1. At this time, temporary adherence between the probes P1, P2 and the micro DUT U1 would lift the micro DUT U1 upward in the restraint direction D2 to leave the bearing plane A1. Then, the protrusive portion 1221 would be there to limit the upward movement of the micro DUT U1, and send the micro DUT U1 back to the bearing plane A1. Upon such an arrangement, aforesaid shortcomings in device dropping can be resolved.

In addition, as shown in FIG. 7, each of the bearing stages 111 is furnished with a vacuum hole H1 for auxiliarily sucking the corresponding micro DUT U1. In the embodiment shown in FIG. 9, the micro DUT U1 is an edge-emitting laser diode able to generate identical laser beams L1, L2 with higher energy and unique color, but not limited thereto. In some other embodiments, the micro DUT U1 can be a micro device to produce low-energy and multi-color beams.

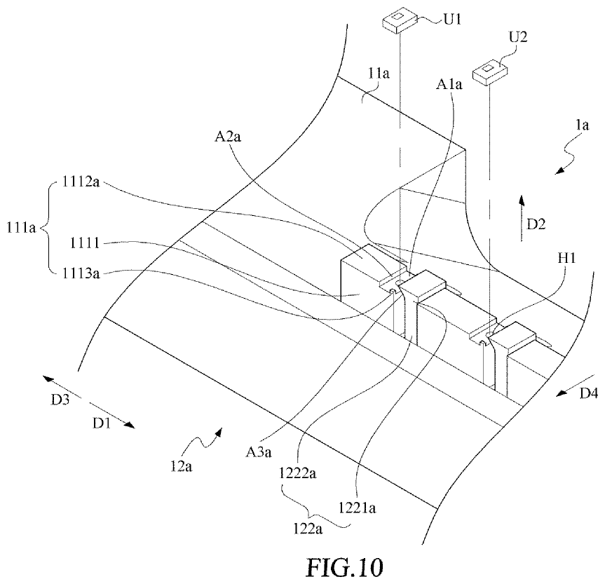

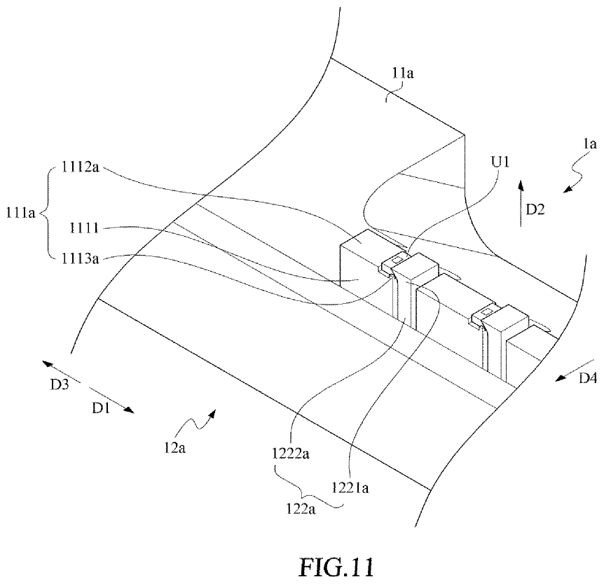

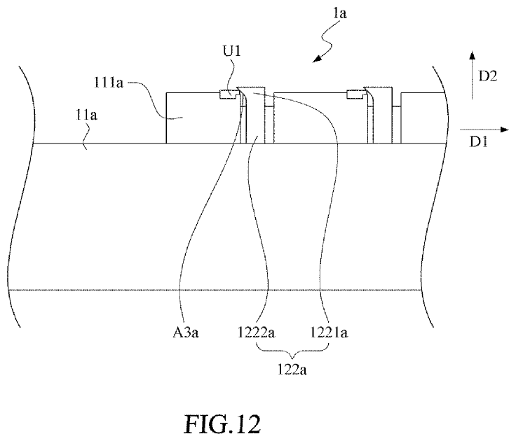

Finally, refer to FIG. 10 through FIG. 12 together; where FIG. 10 demonstrates schematically a process of loading the micro DUT into a second embodiment of the micro DUT carrier in accordance with the present invention, FIG. 11 demonstrates schematically the positioning of the micro DUT loaded in the micro DUT carrier of FIG. 10, and FIG. 12 is a schematic side view of FIG. 11. As shown in FIG. 10, a micro DUT carrier 1a, configured to bear a plurality of micro DUTs U1, U2 (two labeled in the figure), includes a carrier main body 11a, a pusher 12a and a spring (referred to the spring 13 of the first embodiment). In the following description, the micro DUT U1 is raised as an example of these micro DUTs U1, U2. Basically, this embodiment is largely resembled to the aforesaid embodiment. As shown in FIG. 10 and FIG. 11, the major change in this embodiment is at the carrier main body 11a and the pusher 12a. In this embodiment, when the pusher 12a is moved to the opening position, then the micro DUT U1 can be mounted into the carrier main body 11a.

As shown in FIG. 10, the carrier main body 11a includes a plurality of bearing stages 111a (one labeled in the figure). Each of the bearing stages 111a is configured to carry thereon a micro DUT U1. In this embodiment, the bearing stage 111a includes a bearing portion 1111, a restraint portion 1112a and a positioning portion 1113a. Similarly, the bearing portion 1111 has a bearing plane Ala. The restraint portion 1112a is connected with the bearing portion 1111 to form the restraint plane A2a. In this embodiment, though the configuration of the restraint plane A2a is different to that of the restraint plane A2 of FIG. 4, yet the functions thereof are the similar. In addition, in this embodiment, the positioning portion 1113a is disposed on the bearing plane Ala by separating the restraint plane A2a.

As shown in FIG. 10 and FIG. 11, the pusher 12a, disposed at the carrier main body 11a, includes a pusher main body (the same as the pusher main body 121 of the first embodiment shown in FIG. 7) and a plurality of locking elements 122a. Each of the locking elements 122a includes a protrusive portion 1221a and an extension portion 1222a. The protrusive portion 1221a, having an overhead restraint protrusion A3a, is connected with the extension portion 1222a, and extended backward in the extension direction D1. As shown in FIG. 11 and FIG. 12, while in the locking position, the protrusive portion 1221a provides the overhead restraint protrusion A3a thereof to contact against a corner of the micro DUT U1. Further with the bearing portion 1111, the restraint portion 1112a and the positioning portion 1113a, the micro DUT U1 can be secured. By comparing FIG. 12 to FIG. 8, it can be understood that the locking element 122a of this embodiment is shorter and particularly configured to contact against a corner of the micro DUT U1, for a constraint purpose. Hence, the locking element 122a of this embodiment will not interfere the probes P1, P2 (labeled in FIG. 9) from electrically contacting the micro DUT U1, and won't block the generation of the laser beams L1, L2 (labeled in FIG. 9) at the micro DUT U1, either. Therefore, in this embodiment, no cutout is necessary.

Compared to the locking element 122 of this embodiment, the locking element 122a of this embodiment is much regularly shaped. As shown in FIG. 11 and FIG. 12, the extension portion 1222a is shaped to be a rectangle, and the protrusive portion 1221a is shaped to be a 3D structure having a longitudinal trapezoidal cross section (as shown in FIG. 12) and a traverse quadrilateral cross section (as shown in FIG. 11).

In addition, referring to FIG. 10, similar to the first embodiment, each of the bearing stages 111a of this embodiment is furnished with a vacuum hole H1 for auxiliarily vacuuming the micro DUT U1. Since all the bearing stages 111a are structured the same, thus for concisely labeling, the label “H1” is placed at the vacuum hole of the micro DUT U2.

In summary, the present invention utilizes the carrier main body, the pusher and the spring to bear a plurality of micro DUTs, and allows the micro DUTs to be individually energized by a plurality of probes so as to generate a plurality of laser or light beams. In comparison to the prior art, the present invention utilizes the pusher to be controllably moved between the locking position and the opening position. While in the opening position, the carrier main body can be ready to bear the micro DUTs. The elastic resilience of the spring is utilized to send the pusher back to the locking position. Upon such an arrangement, the locking elements can be applied to restrain the micro DUTs on the corresponding bearing stages, and thus the conventional shortcomings in dropping the micro DUTs while the probes are retrieved can be resolved. In addition, in the present invention, the restraint plane of the restraint portion provides a further moving limitation to the micro DUTs in another direction. Further, the present invention further provides the positioning portion to contribute one more moving limitation to the micro DUTs in a further direction. Thus, beside the aforesaid directional moving limitations provided by the present invention, the positioning accuracy of the micro DUTs can be substantially enhanced. Furthermore, the conventional vacuum holes are also provided in the present invention for vacuuming the corresponding micro DUTs auxiliarily in both positioning and moving limitations.

While the present invention has been particularly shown and described with reference to a preferred embodiment, it will be understood by those skilled in the art that various changes in form and detail may be without departing from the spirit and scope of the present invention.

What is claimed is:

1. A micro DUT carrier, applied for bearing a plurality of micro DUTs and allowing the plurality of micro DUTs to be energized individually by a plurality of probes to generate a plurality of light beams, comprising:
a carrier main body, including a plurality of bearing stages separated to each other and arranged in an extension direction, each of the plurality of bearing stages being configured for bearing one of the plurality of micro DUTs;
a pusher, disposed at the carrier main body, controlled to move in the extension direction from a locking position to an opening position, including:
a pusher main body, extending in the extension direction; and
a plurality of locking elements, each of the plurality of locking elements extending from the pusher main body in a restraint direction substantially perpendicular to the extension direction, each of the plurality of locking elements being disposed in a gap between adjacent two of the plurality of bearing stages, each of the plurality of locking elements having a protrusive portion extending backward with respect to the extension direction; wherein, in the locking position, each of the plurality of micro DUTs is restrained correspondingly at each of the plurality of bearing stages; and
a spring, disposed between the carrier main body and the pusher; wherein, after the pusher is controlled to be pushed to the opening position for disposing the plurality of micro DUTs, the spring provides elastic resilience to send the pusher back to the locking position so as to have the plurality of locking elements to restrain correspondingly the plurality of micro DUTs.

2. The micro DUT carrier of claim 1, wherein each of the plurality of bearing stages further includes:
a bearing portion, having a bearing plane for bearing one of the plurality of micro DUTs; and
a restraint portion, connected with the bearing portion to form a restraint plane for contacting against each of the plurality of micro DUTs.

3. The micro DUT carrier of claim 2, wherein each of the plurality of bearing stages further includes a positioning portion disposed on the bearing plane of the bearing portion, separated from the restraint portion, and configured to auxiliarily limit each of the plurality of micro DUTs.

4. The micro DUT carrier of claim 2, wherein each of the plurality of bearing stages further includes a positioning portion disposed on the bearing plane of the bearing portion, connected with the restraint plane of the restraint portion, and configured to auxiliarily limit each of the plurality of micro DUTs.

5. The micro DUT carrier of claim 1, wherein each of the plurality of locking elements further includes an extension portion extended in the restraint direction from the pusher main body and connected with the protrusive portion.

6. The micro DUT carrier of claim 5, wherein the protrusive portion is furnished with a top cutout configured for allowing one of the plurality of probes to enter and then touch electrically corresponding one of the plurality of micro DUTs.

7. The micro DUT carrier of claim 6, wherein the protrusive portion is furnished with a lateral cutout configured to pass therethrough the plurality of light beams upon when the corresponding one of the plurality of micro DUTs is energized by the one of the plurality of probes.

8. The micro DUT carrier of claim 7, wherein the extension portion has an extended positioning wall for contacting against the corresponding one of the plurality of micro DUTs upon when the pusher is moved back to the locking position.

9. The micro DUT carrier of claim 5, wherein the protrusive portion has an overhead restraint protrusion for contacting against the corresponding one of the plurality of micro DUTs upon when the pusher is moved back to the locking position.

10. The micro DUT carrier of claim 1, wherein each of the plurality of bearing stages is furnished with a vacuum hole for auxiliarily sucking one of the plurality of micro DUTs.
